(19) United States
(12) Patent Application Publication
(10) Pub. No.: US 2016/0336460 A1
(43) Pub. Date: Nov. 17, 2016

(54) THIN-FILM TRANSISTOR WITH CARRIER INJECTION STRUCTURE

(71) Applicant: SOOCHOW UNIVERSITY, Suzhou, Jiangsu (CN)

(72) Inventors: Mingxiang WANG, Suzhou (CN); Huaisheng WANG, Suzhou (CN); Dongli ZHANG, Suzhou (CN)

(21) Appl. No.: 15/111,479

(22) PCT Filed: Aug. 15, 2014
(86) PCT No.: PCT/CN2014/084510

§ 371 Date: Jul. 13, 2016

(30) Foreign Application Priority Data
Jan. 23, 2014 (CN) 201410030048.7

(51) Int. Cl. H01L 29/786; H01L 29/78

(52) U.S. Cl. CPC H01L 29/78618; H01L 29/7839; H01L 29/78696

(57) ABSTRACT

A thin-film transistor includes a substrate, a semiconductor channel region, a gate insulating layer, a source region, a drain region, a source electrode, a drain electrode and a gate electrode. The thin-film transistor also includes a carrier injection terminal, and the carrier injection terminal can provide the semiconductor channel region with a carrier of which the polarity is opposite to that of a channel carrier when the thin-film transistor is conducting. The thin-film transistor can significantly reduce device degradation and threshold voltage shift caused by a dynamic hot carrier effect, thereby improving the reliability of a thin-film transistor device and a circuit and simplifying the complexity of the design of a threshold voltage compensation circuit. In addition, the thin-film transistor has low processing difficulty and has no influence on the normal operation of a device.

This application is the national phase of International Application No. PCT/CN2014/084510, titled “THIN-FILM TRANSISTOR WITH CARRIER INJECTION STRUCTURE,” and filed on Aug. 15, 2014, which claims priority to Chinese Patent Application No. 201410030048.7 titled “THIN FILM TRANSISTOR” and filed with the Chinese State Intellectual Property Office on Jan. 23, 2014, both of which are incorporated herein by reference in their entireties.

### FIELD

The present disclosure relates to the technical field of semiconductor, and in particular to a thin-film transistor (TFT) with a structure for injecting a different type of carriers to improve the reliability of a device.

### BACKGROUND

The active matrix organic light-emitting diode (AMOLED) display technology combining the TFT device with organic light-emitting diode (OLED) technology is an important development direction for current and future flat-panel display. For (but not limited to) this application, the reliability of the TFT device is an issue which attracts prevalent attention of the industry.

When a transistor device operates in direct current, a high voltage will generate a high electric field near the drain, which causes a hot carrier effect and leads to degradation in the device performance. In order to reduce the hot carrier effect, the electric field near the drain should be reduced. In the metal-oxide-semiconductor field-effect transistor (MOSFET) device technology related to the technical field of the disclosure, a common method is to introduce a lightly-doped drain (LDD) structure. However, the LDD structure will increase the process difficulty for the TFT device and induce a large parasitic resistance, thereby influencing the on-state characteristics of the device.

Currently, in an AMOLED pixel circuit, threshold voltage compensation is generally realized based on circuit design techniques to deal with threshold voltage shifts caused by long-term operation of the TFT device, which greatly increases the complexity of the drive circuit and the area of the pixel circuit. It is undoubtedly a better solution to suppress the shifts of device characteristics at the device level.

In view of this, a thin-film transistor is provided to improve the reliability of the device.

### SUMMARY

To solve the problems mentioned above, the object of the present disclosure is to provide a thin-film transistor with a carrier injection terminal, to improve reliability of the device by injecting carriers of which the polarity is opposite to the polarity of the channel carriers in an on-state of the thin-film transistor.

To achieve the object mentioned above, following technical solutions are provided according to embodiments of the disclosure.

A thin-film transistor with a carrier injection terminal is provided. The thin-film transistor includes a substrate, a semiconductor channel region, a gate insulating layer, a source region, a drain region, a source electrode, a drain electrode and a gate electrode. The thin-film transistor further includes a carrier injection terminal which provides the semiconductor channel region carriers of which the polarity is opposite to that of the channel carriers in an on-state of the thin-film transistor.

Preferably, the carriers provided by the carrier injection terminal are holes in a case that the channel carriers in an on-state of the thin-film transistor are electrons.

Preferably, the carriers provided by the carrier injection terminal are electrons in a case that the channel carriers in an on-state of the thin-film transistor are holes .

Preferably, the thin-film transistor is a top gate thin-film transistor, a bottom gate thin-film transistor, a dual-gate thin-film transistor, or a surrounding gate thin-film transistor.

Preferably, the carrier injection terminal is one of or a combination of any two or three of a semiconductor junction structure, a metal-semiconductor Schottky junction structure, and a photo-sensitive carriers generation structure.

Preferably, the carrier injection terminal and the semiconductor channel region are located in the same layer or in different layers, and the carrier injection terminal is in direct connection with the semiconductor channel region.

Preferably, the carrier injection terminal is forced with an electrical bias, or with a light excitation, or the combination of both.

Preferably, the semiconductor channel region is made of silicon, germanium, silicon-germanium composite material, oxide semiconductors, organic semiconductors or compound semiconductors.

Preferably, the semiconductor channel region is made of monocrystalline, polycrystalline, microcystalline or amorphous materials.

Preferably, the carrier injection terminal is made of semiconductors, or the combination of semiconductors and metals.

Preferably, the source region or the drain region is made of any one of n-type semiconductors, p-type semiconductors, metals and metal silicides.

The beneficial effects of the disclosure are described as follows.

For high quality, high contents and high refresh rate AMOLED displays, pixel circuits are inevitable to operate under a high frequency condition. Under such condition thin-film transistors in AMOLED display pixel circuits and driver circuits will undergo various dynamic electrical stresses including drain pulse voltage stresses or gate pulse voltage stresses, and non-equilibrium states in the channel will occur which will cause severe degradations to the device characteristics, such as on-state current reduction and threshold voltage shift. To suppress device performance degradations under dynamic electrical stresses, the thin-film transistor according to the disclosure includes a carrier injection terminal which can provide carriers of which the polarity is opposite to that of the channel carriers in an on-state of the thin-film transistor. The injected carriers can suppress the generation of a non-equilibrium state near the drain and the source, lower the amount of defect states generated in a depletion region of the pn junction, reduce device degradation and threshold voltage shifts caused by dynamic hot carrier effect significantly, thereby improving the reliability of thin-film transistor devices and circuits, and reducing the design complexity of a threshold voltage compensation circuit. In addition, fabrication process for the thin-film transistor in the disclosure is compatible with mainstream industry production facilities. The carrier injection terminal has no influence on the normal operation of the device.

### BRIEF DESCRIPTION OF THE DRAWINGS

The drawings to be used in the description of embodiments or the conventional technology are described briefly hereinafter, to make technical solutions according to the embodiments of the disclosure or conventional technology clearer. Apparently, the drawings in the following description only illustrate some embodiments of the disclosure. For those skilled in the art, other drawings may be obtained based on these drawings without any creative effort.

FIG. 1a is a top view of a structure of a thin-film transistor in conventional technology, and Figure lb is a sectional view of the structure in FIG. 1a;

FIG. 2a is a top view of a structure of a thin-film transistor according to the present disclosure; and FIG. 2b is a sectional view of the structure in FIG. 2a;

FIG. 3 is a graph of a comparison between on-state current degradation data of the thin-film transistor in FIGS. 2a and 2b and that of the thin-film transistor in conventional technology;

FIG. 4a is a top view of a structure of a thin-film transistor according to a first embodiment of the disclosure, and FIG. 4b is a sectional view of the structure in FIG. 4a;

FIG. 5a is a top view of a structure of a thin-film transistor according to a second embodiment of the disclosure, and FIG. 5b is a sectional view of the structure in FIG. 5a;

FIG. 6a is a top view of a structure of a thin-film transistor according to a third embodiment of the disclosure, FIG. 6b is a sectional view of the structure in FIG. 6a, and FIG. 6c is a top view of another structure of the thin-film transistor according to the third embodiment of the disclosure;

FIG. 7a is a top view of a structure of a thin-film transistor according to a fourth embodiment of the disclosure, and FIG. 7b is a sectional view of the structure in FIG. 7a;

FIG. 8a is a top view of a structure of a thin-film transistor according to a fifth embodiment of the disclosure, and FIG. 8b is a sectional view of the structure in FIG. 8a; and

FIG. 9a is a top view of a structure of a thin-film transistor according to a sixth embodiment of the disclosure, and FIG. 9b is a sectional view of the structure in FIG. 9a.

### DETAILED DESCRIPTION

The disclosure is described in detail in conjunction with the embodiments illustrated in the drawings. The embodiments are not intended to limit the disclosure, and modifications made on structures, methods or functions according to the embodiments by those skilled in the art fall within the protection scope of the present disclosure.

In addition, labels or marks may be repeatedly used in different embodiments. The repetition is only for brief and clear description of the disclosure, and does not indicate any relations between different embodiments or structures discussed.

In a thin-film transistor circuit, device degradation caused by dynamic electrical stress is a major and common device degradation mechanism in comparison with degradation under direct current or other type stresses. The applicants find that if a supply of a different type of carriers to the channel region can be guaranteed through a specific structure of the device (the different type is a type of carrier of which the polarity is opposite to the polarity of the carrier in the channel when the device is in an on-state, that is, the carriers of the different type are holes in a case that the carriers in the channel are electrons when the device is in the on-state and the carriers of the different type are electrons in a case that carriers in the channel are holes when the device is in the on-state), device degradation such as on-state current reduction and threshold voltage shift may be significantly suppressed and reliability of the device and related circuit can be greatly improved.

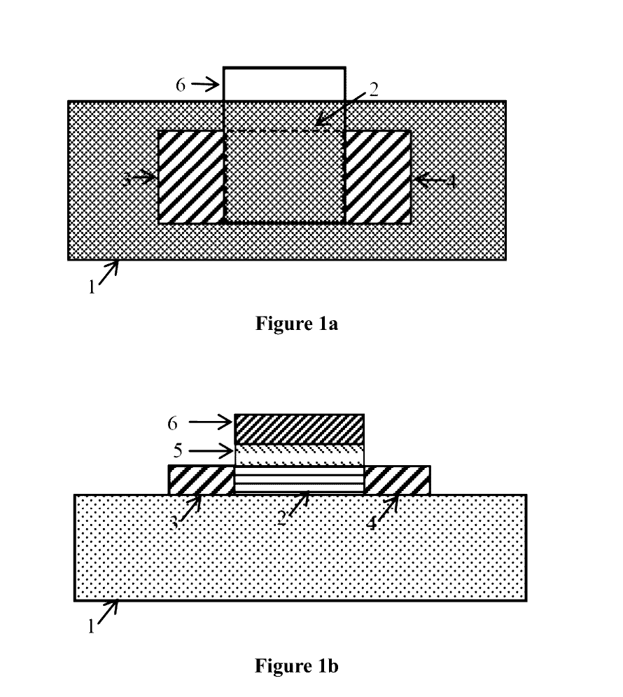

FIGS. 1a and 1b illustrate are structure diagrams of a thin-film transistor with self-aligned top gate in conventional technology. A conventional polycrystalline silicon thin-film transistor is composed of an insulated substrate 1, a semiconductor channel region 2, a source region 3, a drain region 4, a gate insulating layer 5 and a gate electrode 6 (a source electrode and a drain electrode are not shown in the drawings).

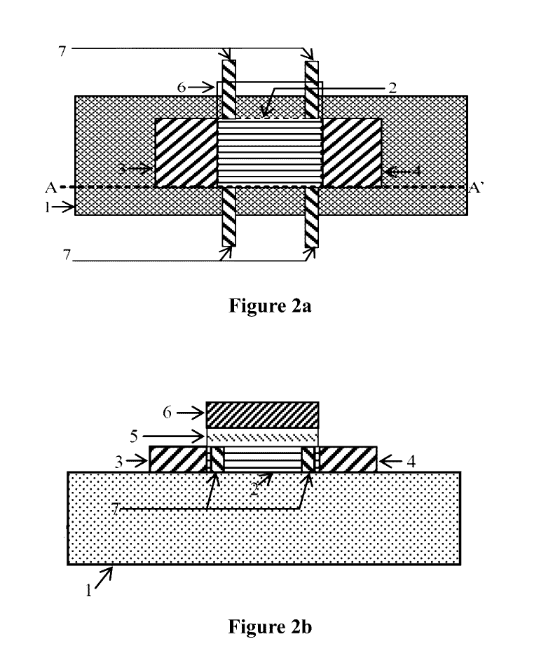

FIGS. 2a and 2b illustrate a structure of a thin-film transistor according to the disclosure. The thin-film transistor includes an insulating substrate 1, a semiconductor channel region 2, a source region 3, a drain region 4, a gate insulating layer 5, a gate electrode 6 and a carrier injection terminal 7 (a source electrode and a drain electrode are not shown in the drawings). A structure of a conventional thin-film transistor, with a carrier injection terminal 7, which supplies a different type of carriers, is provided in the disclosure. The carrier injection terminal 7 can provide carriers of which the polarity is opposite to the polarity of the channel carriers in an on-state of the thin-film transistor to the semiconductor channel region 2.

Specifically, in a case that the channel carriers are electrons in an on-state of the thin-film transistor, the carriers provided by the carrier injection terminal are holes, and in a case that the channel carriers are holes in an on-state of the thin-film transistor, the carriers provided by the carrier injection terminal are electrons.

In the embodiments of the disclosure, the carrier injection terminal 7 and the semiconductor channel region 2 may be located in one layer or in different layers. The carrier injection terminal 7 is in direct connection with the semiconductor channel region 2 no matter they are in one layer or in different layers. The carrier injection terminal 7 is forced with an electrical bias, or with a light excitation, or the combination of both.

In the disclosure, the thin-film transistor is a top gate thin-film transistor, a bottom gate thin-film transistor, a dual-gate thin-film transistor, or a surrounding gate thin-film transistor.

Further, the carrier injection terminal 7 is one of or a combination of any two or the three of a semiconductor junction structure, a metal-semiconductor Schottky junction structure, and a photo-sensitive carriers generation structure.

Preferably, the semiconductor channel region 2 is made of silicon, germanium, a silicon-germanium composite material, an oxide semiconductor materials such as indium-gallium-zinc oxide and zinc oxide, an organic semiconductors or compound semiconductors; the semiconductor channel region 2 is made of monocrystalline, polycrystalline, microcrystalline or amorphous; the carrier injection terminal 7 may be made of a material which is the same as or different from the material for the semiconductor channel region 2; in addition, the carrier injection terminal 7 is made of semiconductors, or the combination of semiconductors and metals.

In the thin-film transistor provided in the disclosure, the source region and drain region is made of any one of n-type semiconductors, p-type semiconductors, metals and metal silicides.

Operating principles of the structure of the thin-film transistor in the disclosure is as follows. When a pulse voltage is applied to the gate electrode of the thin-film transistor, if an edge of the pulse voltage rises or falls too fast, the concentration of the carriers in the channel changes too slowly to catch up with the change of the gate voltage, which causes the channel to be in a non-equilibrium state. There are pn junctions between the channel and the source as well as between the channel and the drain, and depletion regions formed between the channel and the source and between the channel and the drain are extended through ionization emission of defect states in the channel region, where the carriers are accelerated to hot carriers through the electric field in the depletion region. As shown in FIGS. 2a and 2b, the carrier injection terminal 7 which injects different types of carriers is introduced near the source and the drain in the disclosure, and the carrier injection terminal 7 may provide carriers as the gate voltage changes in time, which suppresses the formation of non-equilibrium state near the source and the drain, and reduces amount of the defect states generated in the depletion region of the pn junctions, thus degradation caused by pulse voltage stress is suppressed.

FIG. 3 is a graph of a comparison between on-state current degradation data of the thin-film transistor in the present disclosure and that in conventional technology under a same gate pulse voltage, where values of the gate pulse voltage Vg range between −10V and 10V and the rise time tr and fall time tf of the pulse voltage are both 100 ns.

As can be seen from FIG. 3, if the carrier injection terminal is grounded, the degradation of the on-state current after stress is significantly suppressed, and if an appropriate positive bias voltage (2V in FIG. 3) is applied to the carrier injection terminal, the degradation of the on-state current of the device is further reduced. Based on the calculation for the degradation of the on-state current of the device, lifetime of a TFT device with carrier injection terminal may be increased by more than ten times.

The disclosure is further described in conjunction with specific embodiments.

### The First Embodiment

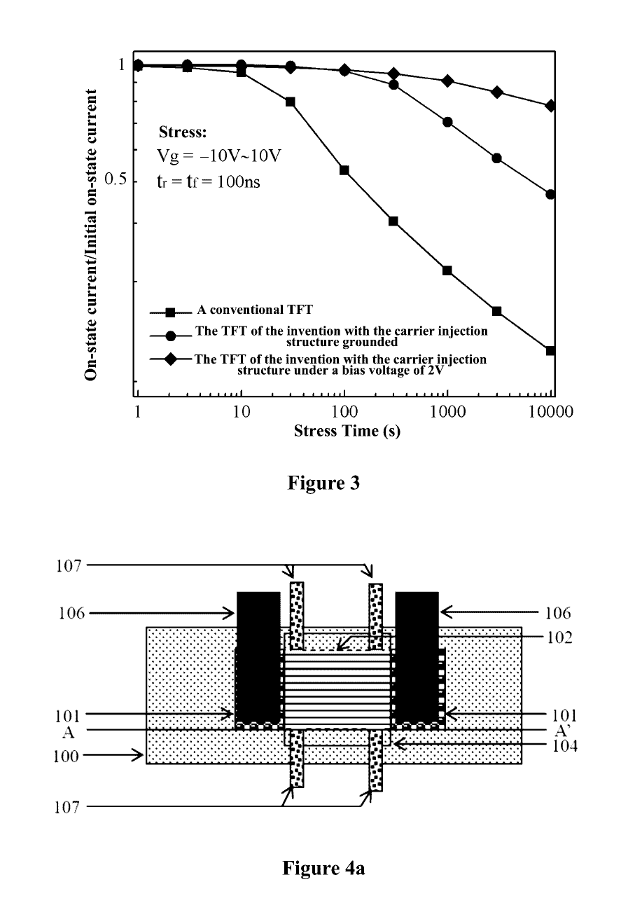

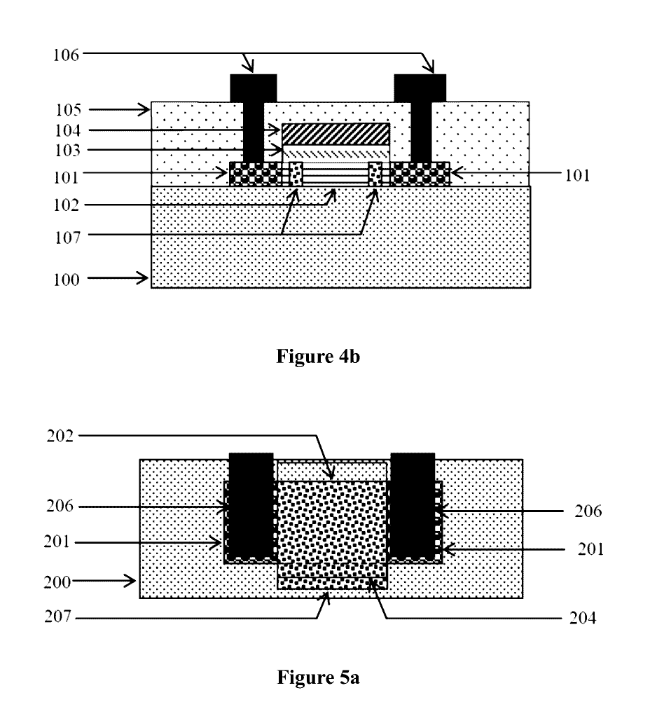

As shown in FIGS. 4a and 4b, a structure of a thin-film transistor according to the embodiment is a self-aligned top gate structure. The structure includes an insulated substrate 100, a source and drain region 101, a semiconductor channel region 102, a gate insulating layer 103, a gate electrode 104, a passivation layer 105, a source and drain electrode 106 and a carrier injection region 107.

The carrier injection terminal 107 and the semiconductor channel region 102 are in one layer, where the carrier injection terminal 107 is on both sides of the semiconductor channel region 102 and is in direct connection with the semiconductor channel region 102. The carrier injection region 107 is to provide carriers to the semiconductor channel region 102.

It should be noted that, the carrier injection terminal 107 and the semiconductor channel region 102 according to the first embodiment of the disclosure are in one layer. The carrier injection terminal 107 and the semiconductor channel region 102 may be located in different layers alternatively, as described in the second and third embodiments.

### The Second Embodiment

As shown in FIGS. 5a and 5b, a structure of a thin-film transistor according to the embodiment is a self-aligned top gate structure. The structure includes an insulated substrate 200, a source and drain region 201, a semiconductor channel region 202, a gate insulating layer 203, a gate electrode 204, a passivation layer 205, a source and drain electrode 206 and a carrier injection terminal 207.

The carrier injection terminal 207 is located under and in direct connection with the semiconductor channel region 202, and may provide carriers to the semiconductor channel region 202.

### The Third Embodiment

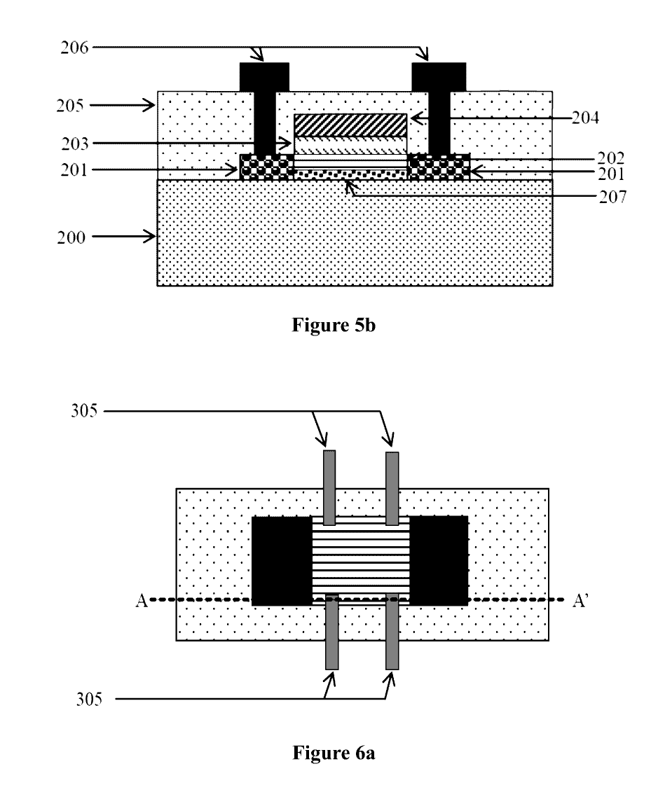

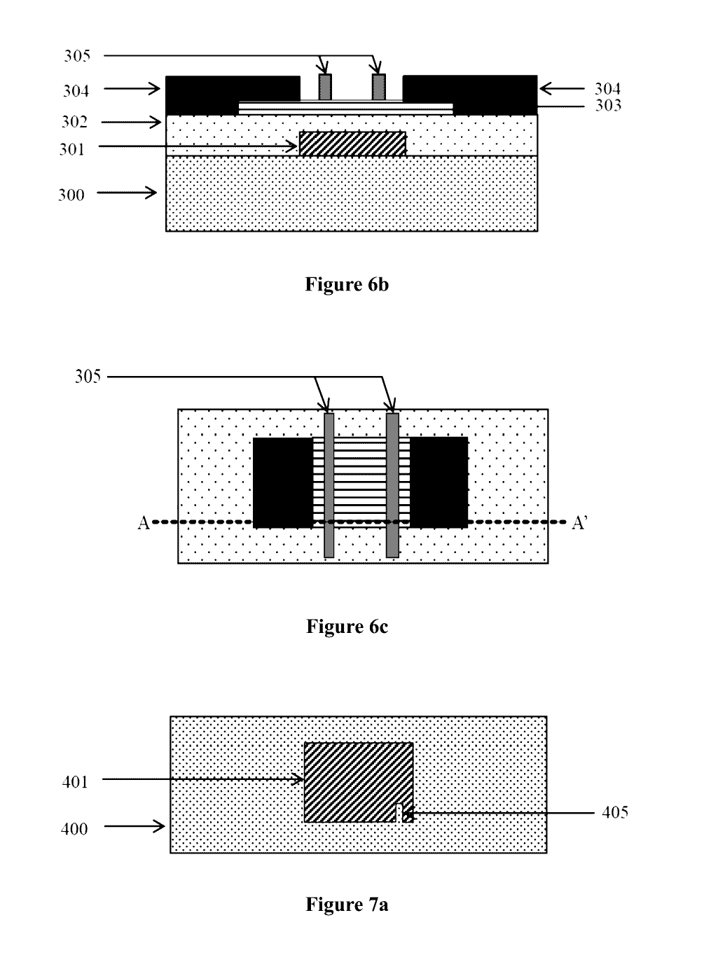

As shown in FIGS. 6a and 6b, a structure of a thin-film transistor according to the embodiment is a bottom gate structure. The structure includes an insulated substrate 300, a gate electrode 301, a gate insulating layer 302, a semiconductor channel region 303, a source and drain electrode 304 and a carrier injection terminal 305.

The carrier injection terminal 305 is located above and in direct connection with the semiconductor channel region 303. Carriers can be provided to the channel by the carrier injection terminal 305 through the contact area of the carrier injection terminal 305 and the semiconductor channel region 303.

According to the embodiment shown in FIG. 6a, the carrier injection terminal 305 adopts segmented design, and no carrier injection terminal is provided in the middle of the semiconductor channel region 303. Of course, in another embodiment as shown in FIG. 6c, the carrier injection terminal 305 may be across the whole semiconductor channel region 303.

### The Fourth Embodiment

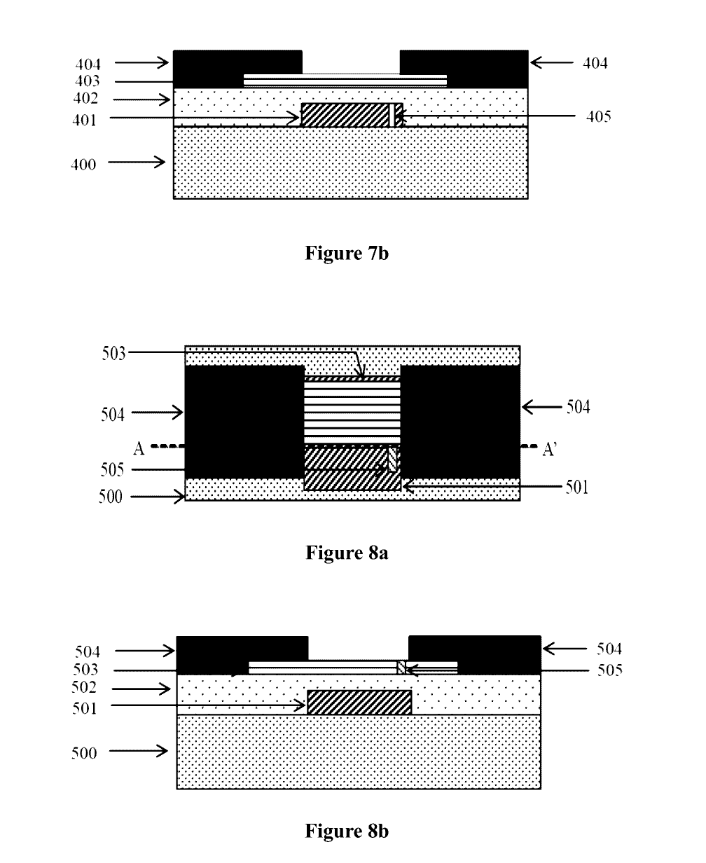

As shown in FIGS. 7a and 7b, a structure of a thin-film transistor according to the embodiment is a bottom gate structure. The structure includes a transparent insulated substrate 400, a gate electrode 401, a gate insulating layer 402, a semiconductor channel region 403, a source and drain electrode 404 and a photo-sensitive carriers generation structure 405.

The photo-sensitive carriers generation structure 405 and the gate electrode 401 are provided in one layer. Light irradiates from below the transparent insulated substrate 400 to a part of the semiconductor channel region 403 through the transparent insulated substrate 400 and the photo-sensitive carriers generation structure 405, thus carriers is provided to the channel region 403.

### The Fifth Embodiment

As shown in FIGS. 8a and 8b, a structure of a thin-film transistor according to the embodiment is a bottom gate structure. The structure includes an insulated substrate 500, a gate electrode 501, a gate insulating layer 502, a semiconductor channel region 503, a source and drain electrode 504 and a photo-sensitive carriers generation structure 505.

The photo-sensitive carriers generation structure 505 and the semiconductor channel region 503 are located in one layer. Light irradiates from above the thin-film transistor to the carrier injection terminal 505, photo-generated carriers may be generated in this structure and different types of carriers are provided to the channel region 503 through the structure.

### The Sixth Embodiment

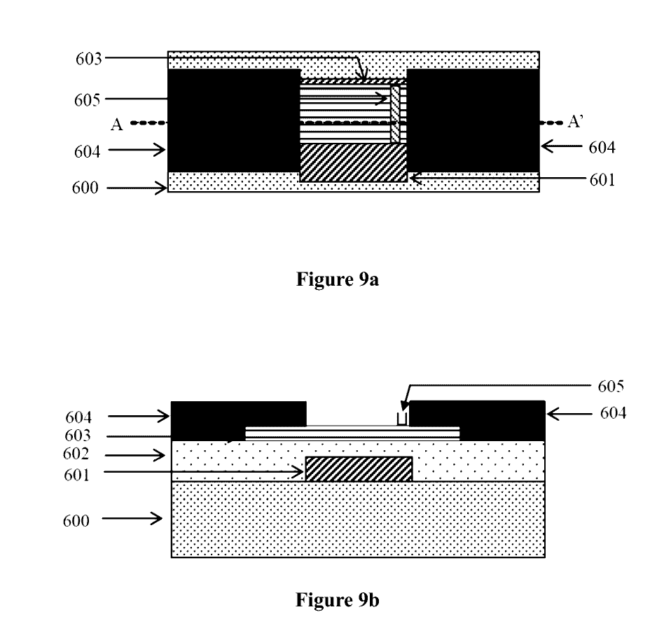

As shown in FIGS. 9a and 9b, a structure of a thin-film transistor according to the embodiment is a bottom gate structure. The structure includes an insulated substrate 600, a gate electrode 601, a gate insulating layer 602, a semiconductor channel region 603, a source and drain electrode 604 and a photo-sensitive carriers generation structure 605.

The photo-sensitive carriers generation structure 605 is provided above and in direct connection with the semiconductor channel region 603. Light irradiates from above the thin-film transistor to the carrier injection terminal 605, photo-generated carriers may be generated in this region and different types of carriers are provided to the channel region 603 through the structure.

The carrier injection terminal according to the embodiments described above is one of a semiconductor junction structure, a metal-semiconductor Schottky junction structure, and a photo-sensitive carriers generation structure, which can provide carriers of which the polarity is opposite to the polarity of a channel carriers when a TFT is turned on. Of course, in another embodiment, the carrier injection terminal may be a combination of two or three of a semiconductor junction structure, a metal-semiconductor Schottky junction structure, and a photo-sensitive carriers generation structure, and the principle is the same as in the embodiments described above, which is not repeated herein.

As can be seen from the technical solutions mentioned above, the thin-film transistor according to the disclosure may significantly reduce device degradation and threshold voltage shifts caused by a dynamic electrical stresses, improve the reliability of a TFT devices and circuits and simplify the design complexity of a threshold voltage compensation circuits. In addition, process difficulty for the thin-film transistor in the disclosure is low and the introduction of the carrier injection terminal has no influence on the normal operation of the device.

Apparently, for those skilled in the art, the disclosure is not limited to details of the exemplary embodiments mentioned above, and can be realized in other specific forms without departing from the spirit or basic characteristics of the disclosure. Thus, the embodiments described herein are exemplary rather than restrictive in all respects. Since the scope of the present disclosure is limited by the claims instead of foregoing description, all changes within the meaning and range of equivalency of the claims fall in the scope of the disclosure. Any drawing sign of the claims shall not be considered as limitation to the related claims.

In addition, it should be understood that, each embodiment does not only include one independent technical solution although the disclosure is described through embodiments for clarity. Those skilled in the art should treat the disclosure as a whole, and other understandable embodiments may be obtained through proper combination of the technical solutions in the embodiments.

1. A thin-film transistor with a carrier injection terminal, comprising:
a substrate;
a semiconductor channel region;
a gate insulating layer;
a source region;
a drain region;
a source electrode;
a drain electrode;
a gate electrode; and
a carrier injection terminal, which is forced with an electrical bias or with a light excitation, or the combination of both, and provides the semiconductor channel region with carriers of which the polarity is opposite to that of the channel carriers in an on-state of the thin-film transistor.

2. The thin-film transistor according to claim 1, wherein the carriers provided by the carrier injection terminal are holes in a case that the channel carriers in the on-state of the thin-film transistor are electrons.

3. The thin-film transistor according to claim 1, wherein the carriers provided by the carrier injection terminal are electrons in a case that the channel carriers in the on-state of the thin-film transistor are holes.

4. The thin-film transistor according to claim 1, wherein the thin-film transistor is a top gate thin-film transistor, a bottom gate thin-film transistor, a dual-gate thin-film transistor, or a surrounding gate thin-film transistor.

5. The thin-film transistor according to claim 1, wherein the carrier injection terminal is one of or a combination of any two or three of a semiconductor junction structure, a metal-semiconductor Schottky junction structure, and a photo-sensitive carriers generation structure.

6. (canceled)

7. The thin-film transistor according to claim 1, wherein the carrier injection terminal and the semiconductor channel region are located at the same layer or at different layers, and the carrier injection terminal is in direct connection with the semiconductor channel region.

8. (canceled)

9. The thin-film transistor according to claim 1, wherein the semiconductor channel region is made of silicon, germanium, silicon-germanium composite material, oxide semiconductors, organic semiconductors or compound semiconductors.

10. The thin-film transistor according to claim 1, wherein the semiconductor channel region is made of monocrystalline, polycrystalline, microcystalline or amorphous materials.

11. The thin-film transistor according to claim 1, wherein the carrier injection terminal is made of semiconductors, or the combination of semiconductors and metals.

12. The thin-film transistor according to claim 1, wherein the source region or the drain region is made of any one of n-type semiconductors, p-type semiconductors, metals and metal silicides.

13. The thin-film transistor according to claim 1, the carrier injection terminal is forced with a negative electrical bias, or a positive electrical bias, or grounded.

14. The thin-film transistor according to claim 7, the carrier injection terminal is made of a material the same as or different from the channel semiconductor material.
